(19) United States
(12) Patent Application Publication
(10) Pub. No.: US 2011/0290536 A1
(43) Pub. Date: Dec. 1, 2011

(54) WIRING SUBSTRATE

(75) Inventors: Kentaro Kaneko, Nagano (JP); Hitoshi Kondo, Nagano (JP); Kotaro Kodani, Nagano (JP); Tomoyuki Shimodaira, Nagano (JP)

(73) Assignee: SHINKO ELECTRIC INDUSTRIES CO., LTD., Nagano (JP)

(21) Appl. No.: 13/093,915

(22) Filed: Apr. 26, 2011

(30) Foreign Application Priority Data
Jun. 1, 2010 (JP) 2010-126238

(51) Int. Cl. H05K 1/02; H05K 1/00

(52) U.S. Cl. 174/251; 174/258

(57) ABSTRACT

A wiring substrate includes a wiring layer, and an insulating layer configured to cover the wiring layer, wherein the insulating layer is recognized to have any color in a range from purple to blue.

### CROSS-REFERENCE TO RELATED APPLICATIONS

This patent application is based upon and claims the benefit of priority of the prior Japanese Patent Application No. 2010-126238 filed on Jun. 1, 2010, the entire contents of which are incorporated herein by reference.

### FIELD

A certain aspect of the embodiments discussed herein is related to a wiring substrate having a wiring layer and an insulating layer coating the wiring layer.

### BACKGROUND

FIG. 1 is a plan view of an example wiring substrate. FIG. 2 is a cross-sectional view taken along a line A-A of FIG. 1. Referring to FIG. 1 and FIG. 2, an example wiring substrate 100 has a structure in which a first insulating layer 110, a wiring layer 120 and a second insulating layer 130 are sequentially laminated.

The first insulating layer 110 is a layer for forming the wiring layer 120 and formed by an insulating resin or the like. The wiring layer 120 is formed by copper (Cu) or the like. The second insulating layer 130 is formed to cover the wiring layer 120 on the first insulating layer 110 and formed by an insulating resin or the like. The second insulating layer 130 has an opening portion 130x, and a part of the wiring layer 120 is exposed inside the opening portion 130x.

Ordinarily, a material of the second insulating layer 130 is a colorless resin having relatively high brightness. As illustrated in FIG. 1, the wiring layer 120 covered by the second insulating layer 130 may be seen through beyond the second insulating layer 130.

During a manufacturing process of the wiring substrate, various checks are carried out. At a time of inspection, a wiring substrate may be automatically positioned in an inspection apparatus using an image analysis. However, if the color tone or the brightness of the wiring layer seen through the second insulating layer 130 changes, all photographing conditions or all image analyzing conditions may be changed. In this case, the changing of the conditions may cause a lot of trouble.

As a countermeasure, Japanese Patent No. 3821993 proposes coloring of an insulating layer covering a wiring layer. Specifically, when the insulating layer covering the wiring layer is measured and displayed by a method stipulated by Japanese Industrial Standards JISZ8721, a range of the color phase is 2.5B to 10Y via 10G, a chroma saturation C of 1.5 or more, the brightness V is 2 or more, and the color is greenish chromatic color.

However, even if the insulating layer covering the wiring layer is colored to be greenish, a degree of seeing through the lower wiring layer may be improved but still insufficient. For example, if the insulating layer covering the wiring layer is colored greenish, the lower wiring layer seen through beyond the insulating layer may still be recognized as defective and accuracy and efficiency of outer inspection may still occur.

### SUMMARY

According to an aspect of the embodiment, a wiring substrate includes a wiring layer, and an insulating layer configured to cover the wiring layer, wherein the insulating layer is recognized to have any color in a range from purple to blue.

### MEANS FOR SOLVING THE PROBLEM

The object and advantages of the invention will be realized and attained by means of the elements and combinations particularly pointed out in the appended claims.

It is to be understood that both the foregoing general description and the following detailed description are exemplary and explanatory and are not restrictive of the invention, as claimed.

### BRIEF DESCRIPTION OF THE DRAWINGS

FIG. 1 is a plan view of an example wiring substrate;

FIG. 2 is a cross-sectional view taken along a line A-A of FIG. 1;

FIG. 3 is a plan view of an example wiring substrate of an Embodiment;

FIG. 4 is a cross-sectional view taken along a line B-B of FIG. 3;

FIG. 5 illustrates a manufacturing step 1 of the wiring substrate of the Embodiment;

FIG. 6 illustrates a manufacturing step 2 of the wiring substrate of the Embodiment;

FIG. 7 illustrates a manufacturing step 3 of the wiring substrate of the Embodiment;

FIG. 8 illustrates a manufacturing step 4 of the wiring substrate of the Embodiment;

FIG. 9 illustrates a manufacturing step 5 of the wiring substrate of the Embodiment;

FIG. 10 illustrates a manufacturing step 6 of the wiring substrate of the Embodiment;

FIG. 11 illustrates a manufacturing step 7 of the wiring substrate of the Embodiment;

FIG. 12 illustrates a manufacturing step 8 of the wiring substrate of the Embodiment;

FIG. 13 is a plan view of an example wiring substrate used for simulation;

FIG. 14 is a cross-sectional view taken along a line C-C of FIG. 13; and

FIG. 15 illustrates luminance differences between the wiring layer and the second insulating layer.

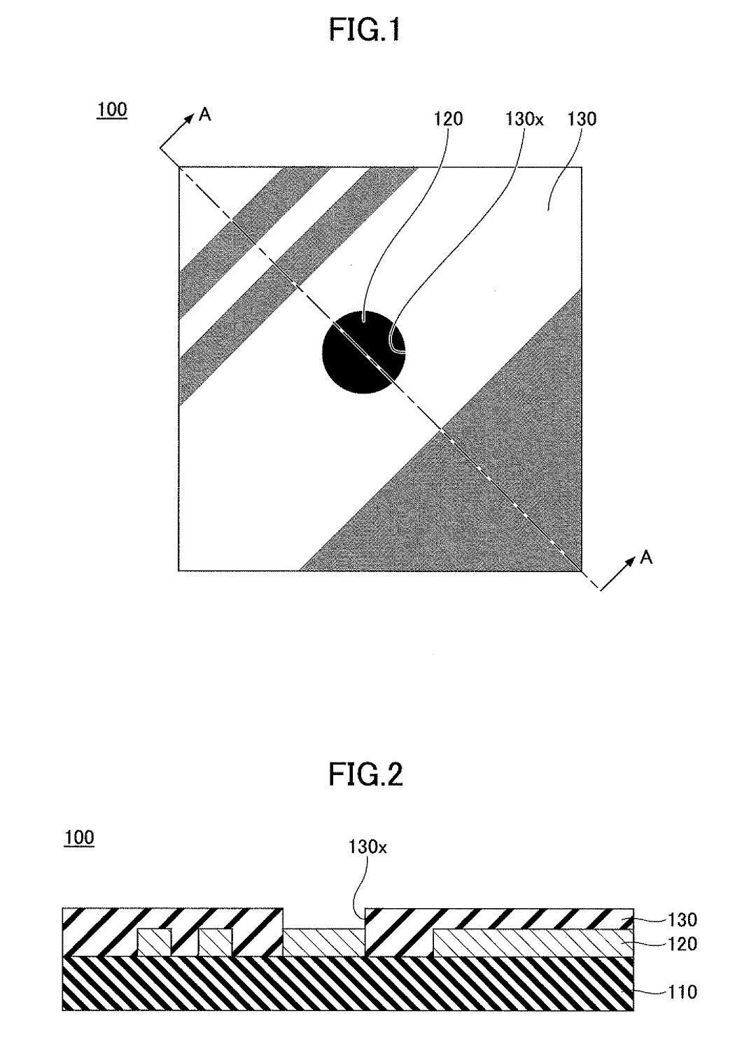

### DESCRIPTION OF EMBODIMENT

As described previously, the insulating layer may be colored.

However, even if the insulating layer covering the wiring layer is colored to be greenish, a degree of seeing through the lower wiring layer may be improved but still insufficient. For example, if the insulating layer covering the wiring layer is colored greenish, the lower wiring layer seen through beyond the insulating layer may still be recognized as being defective and accuracy and efficiency of outer inspection may still occur.

Preferred embodiments of the present invention will be explained with reference to accompanying drawings. The same reference numerals are provided to the corresponding portions and description of these portions is omitted.

### [Structure of Wiring Substrate]

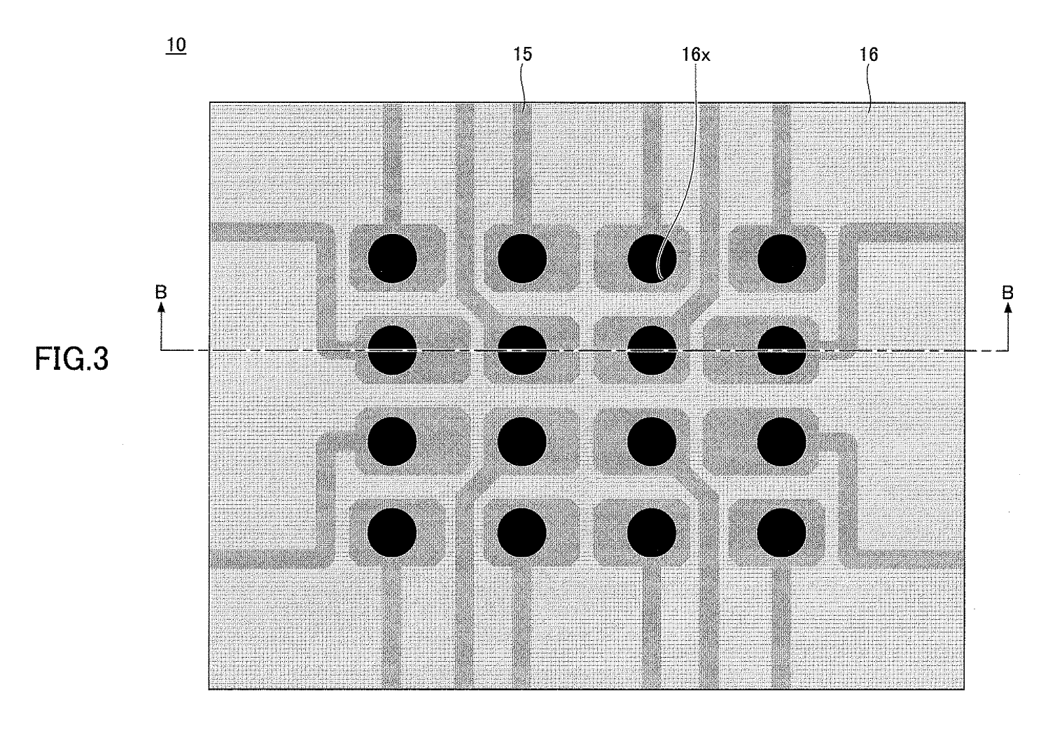

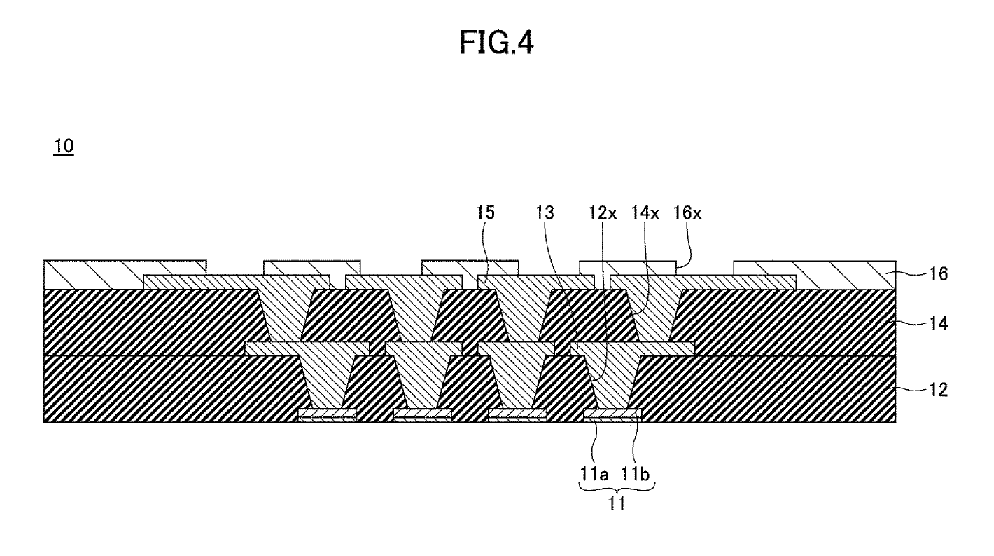

First, the structure of a wiring substrate of the Embodiment is described. FIG. 3 is a plan view of an example wiring substrate of the embodiment. FIG. 4 is a cross-sectional view taken along a line B-B of FIG. 3. Referring to FIG. 3 and FIG. 4, the wiring substrate 10 of the embodiment has a structure in which a first wiring layer 11, a first insulating layer 12, a second wiring layer 13, a second insulating layer 14, third wiring layers 15 and a third insulating layer 16 are sequentially laminated.

The first wiring layer 11 is in the lowermost layer of the wiring substrate 10. The first wiring layer 11 includes a first layer 11a and a second layer 11b. Apart of the first layer 11a included in the first wiring layer 11 is exposed from the first insulating layer 12 and functions as an electrode pad connected to a semiconductor chip or the like. The first layer 11a may be a conductive layer formed by sequentially laminating a gold (Au) film, a palladium (Pd) film and a nickel (Ni) film in this order with the gold (Au) layer being exposed to the outside. The second layer 11b is a conductive layer including a copper (Cu) or the like. The thicknesses of the first wiring layer 11 is about 10 to 30 μm.

The first insulating layer 12 covers a part of an upper surface (a face connected to a via wiring of the second wiring layer 13) and a side surface of the first wiring layer 11. A lower surface (a surface opposite to a surface connected to the via wiring of the second wiring layer 13) is exposed to the outside. The material of the first insulating layer 12 may be an insulating resin such as an epoxy resin and a polyimide resin. The thickness of the first insulating layer 12 is about 50 μm.

The second wiring layer 13 is formed on the first insulating layer 12. The second wiring layers 13 include via wirings which penetrate through the first insulating layer 12 and filled inside first via holes 12x exposing the upper surfaces of the first wiring layers 11, and wiring patterns formed on the first insulating layer 12. The second wiring layers 13 are electrically connected to the first wiring layer 11 exposed toward the first via holes 12x. The material of the second wiring layers 13 may be made of copper (Cu) or the like. The thicknesses of a wiring pattern forming the second wiring layers 13 may be about 15 to 20 μm.

The second insulating layer 14 is formed to cover the second wiring layer 13 on the first insulating layer 12. The material of the second insulating layer 14 may be an insulating resin such as an epoxy resin and a polyimide resin. The thickness of the second insulating layer 14 may be about 50 μm.

The third wiring layers 15 are formed on the second insulating layer 14. The third wiring layers 15 include via wirings which penetrate through the second insulating layer 14 and filled inside second via holes 14x exposing the upper surfaces of the second wiring layers 13, and wiring patterns formed on the second insulating layer 14. The third wiring layers 15 are electrically connected to the second wiring layers 13 exposed toward the second via holes 14x. The material of the third wiring layers 15 may be copper (Cu) or the like. The thicknesses of the third wiring layers 15 may be about 15 to 20 μm.

The third insulating layer 16 is formed to cover the third wiring layers 15 on the second insulating layer 14. The third insulating layer 16 functions as a so-called solder resist layer. The thickness of the third insulating layer 16 may be about 50 μm. The third insulating layer 16 includes opening portions 16x. Parts of the third wiring layers 15 are exposed inside opening portions 16x of the third insulating layer 16. When necessary, metallic layers or the like may be formed on the third wiring layers 15 which are exposed toward insides of the opening portions 16x. An example of the metallic layers is an Au layer, a Ni/Au layer which is a metallic layer formed by laminating a Ni layer and an Au layer in this order, a Ni/Pd/Au layer which is a metallic layer formed by laminating a Ni layer, a Pd layer, and an Au layer in this order or the like.

External connection terminals such as a solder ball or a lead pin may be formed on the third wiring layers 15 which are exposed toward insides of the opening portions 16x of the third insulating layer 16 or on the metallic layers when the metallic layers are formed on the third wiring layers 15. The externally connecting terminal is electrically connected to pads provided in a mounting board (not illustrated) such as a motherboard, and can be formed when necessary. However, the third wiring layers 15 exposed to the insides of the opening portions 16x (when metallic layers or the like are formed on the third wiring layers 15, the metallic layers or the like) may be an external connection terminal.

With this Embodiment, the third insulating layer 16 being the uppermost layer is visible as a color in a wavelength range between purple and blue. The color in the wavelength range between purple and blue belongs to a color phase range between 5B and 10RP via 5P on the color phase circle measured and displayed by a method stipulated by Japanese Industrial Standards JISZ8721. Said differently, the material of the third insulating layer 16 strongly reflects a visible ray of a wavelength in a range of 385 nm<the wavelength≦495 nm (a range between purple and blue). Said differently, the material of the third insulating layer 16 strongly reflects a visible ray of a wavelength range satisfying 385 nm<the wavelength≦495 nm (a range between purple and blue).

As described, there is a case where the insulating layer is made of a colorless material having a relatively high brightness. In this case, the lower wiring layer may be seen through the insulating layer. In order to improve a degree of seeing through the lower wiring layer, the insulating layer may be colored to be greenish, as described.

The greenish color has the wavelength range satisfying 495 nm<the wavelength≦570 nm. Therefore, in this case, the material of the insulating layer has a peak of reflectance of visible ray in any of wavelengths satisfying 495 nm<the wavelength≦570 nm (greenish range). With the embodiment, the material of the third insulating layer 16 is visible as any of colors in a range from purple having a wavelength shorter than green to blue, it is possible to improve a degree of seeing through the third wiring layers 15 positioned lower than the third insulating layer 16. Further, it is confirmed that this result does not depend on the chroma saturation and the brightness. These factors were introduced during the time the inventors performed repeated experiments. Detailed experimental results will be explained in the following Examples and Comparative Examples later. FIG. 3 is a schematic view of the third insulating layer 16 through which the third wiring layer 15 is slightly seen.

The material which can be used as the material of the third insulating layer 16 and recognized to have any of the colors in the range from purple to blue is an epoxy resin containing a pigment having a reflectance peak of the visible ray in any of the wavelength range satisfying 385 nm<the wavelength≦495 nm.

A material visible as purple may be an epoxy resin containing a polycyclic pigment having a reflectance peak of visible rays having any of wavelengths in a range (the wavelength range of purple) satisfying 385 nm<the wavelength≦450 nm such as anthraquinone, oxazine, quinacridone, perylene, indigoid, imidazolone, xanthene, carbonium, and violanesolone.

A material visible as blue may be an epoxy resin containing a polycyclic pigment having a reflectance peak of visible rays having any of wavelengths in a range (the wavelength range of blue) satisfying 450 nm<the wavelength≦495 nm such as phthalocyanine, anthraquinone, indigoid, and carbonium. A material visible as blue may be an epoxy resin containing an inorganic pigment having a reflectance peak of visible rays having any of wavelengths in a range (the wavelength range of blue) satisfying 450 nm<the wavelength≦495 nm such as ultramarine blue and prussia blue (potassium ferrocyanide).

However, the epoxy resin is only an example of resin used in the Embodiment. It is not limited to the epoxy resin and another insulating resin such as polyimide resin may be used. Meanwhile, as long as the pigment has the reflectance peak of the visible light of any of the wavelength range from purple to blue satisfying 385 nm<the wavelength≦495 nm, an insulating resin containing the pigment other than the above-mentioned pigment may be used.

### [Manufacturing Method of the Wiring Substrate]

First, a manufacturing method of a wiring substrate of the Embodiment is described. FIG. 5 to FIG. 12 illustrate example manufacturing steps of the wiring substrate of the Embodiment.

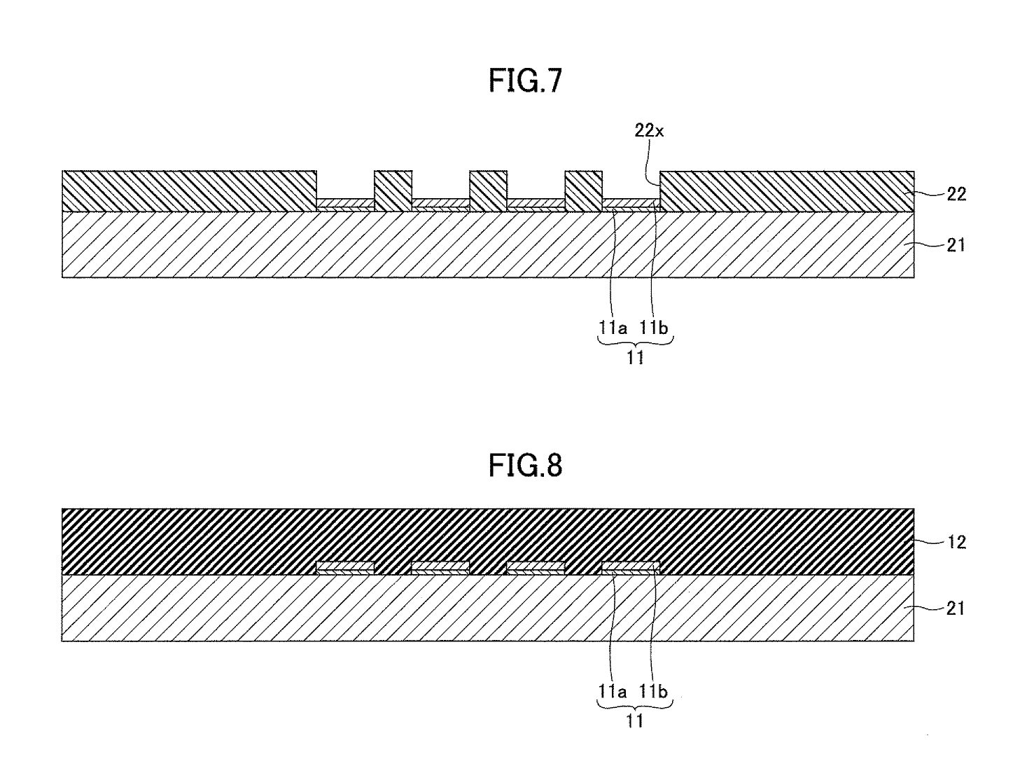

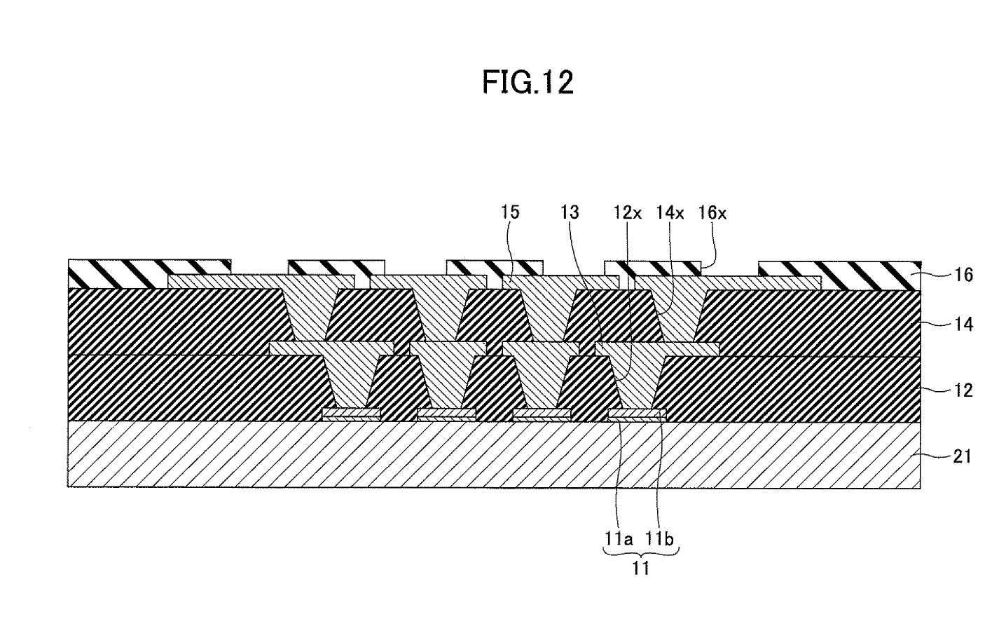

Referring to FIG. 5, a supporting body 21 is prepared. The supporting body 21 is a silicon plate, a glass plate, a metallic plate, a metallic foil, or the like. A copper foil is used as the supporting body 21 in the Embodiment. This is because the supporting body is used as a power supply layer for electro plating in the step illustrated in FIG. 7 described below. The supporting body 21 can be easily removed after the step illustrated in FIG. 12 described below. The thickness of the supporting body 21 may be about 35 to 100 μm.

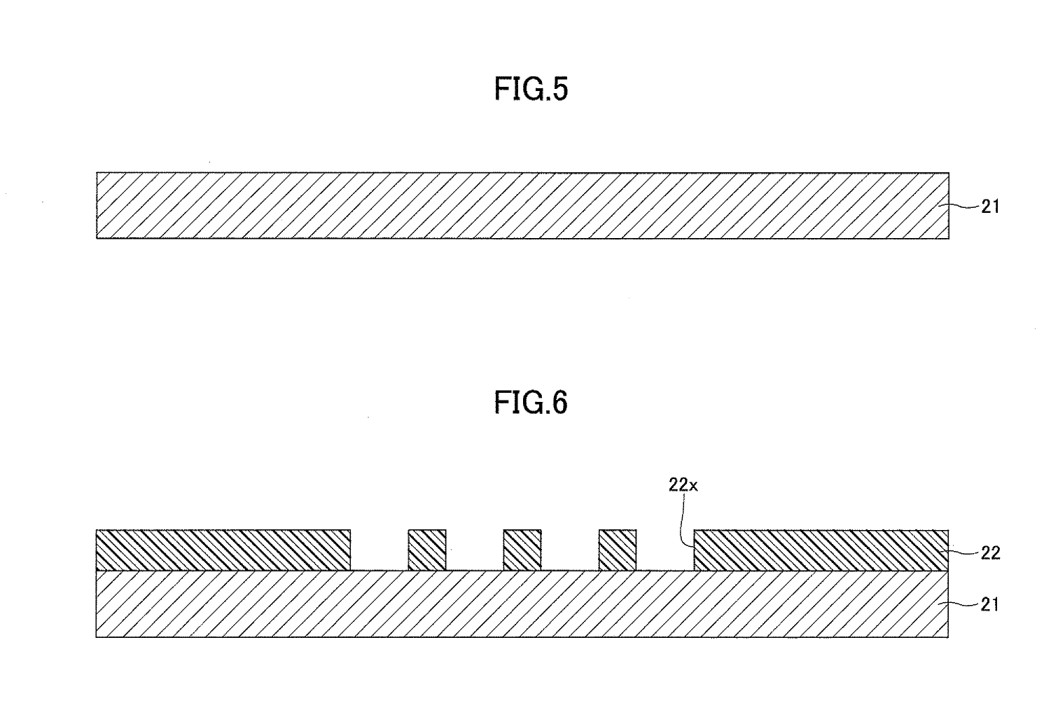

In the step illustrated in FIG. 6, a resist layer 22 having an opening portion 22x corresponding to the first wiring layer 11 is formed on one surface of the supporting body 21. Specifically, a liquid or paste resist made of a photosensitive resin material such as an epoxy or imide resin is coated on one face of the supporting body 21. Alternatively, a film resist such as a dry film resist made of a photosensitive resin material containing an epoxy resin, an imide resin or the like is laminated on the one face of the supporting body 21. By irradiating the coated or laminated resist with light and developing the coated or laminated resist, opening portions 22x are formed. With this, the resist layer 22 having the opening portions 22x is formed. It is possible to laminate a film resist previously having the opening portions 22x on the one face of the supporting body 21.

The opening portions 22x are formed at positions corresponding to the first wiring layer 11 formed in the step illustrated in FIG. 7. However, a pitch of arranging the opening portions 22x may be about 100 μm. The opening portions 22x may be shaped like a circle in a plan view and have a diameter of about 50 μm.

In the step illustrated in FIG. 7, the first wiring layer 11 including a first layer 11a and a second layer 11b is formed inside the opening portions 22x on the one surface of the supporting body 21 by electro plating or the like using the supporting body 21 as the power supply layer.

The first layer 11a has a structure formed by sequentially laminating a gold (Au) film, a palladium (Pd) film and a nickel (Ni) film in this order. In order to form the first wiring layer 11, first layer 11a is formed by sequentially plating the gold (Au) film, the palladium (Pd) film and the nickel (Ni) film in this order by electro plating or the like using the supporting body 21 as the power supply layer, and then the second layer lib made of copper (Cu) or the like is formed on the first layer 11a by an electro plating using the supporting body 21 as the power supply layer.

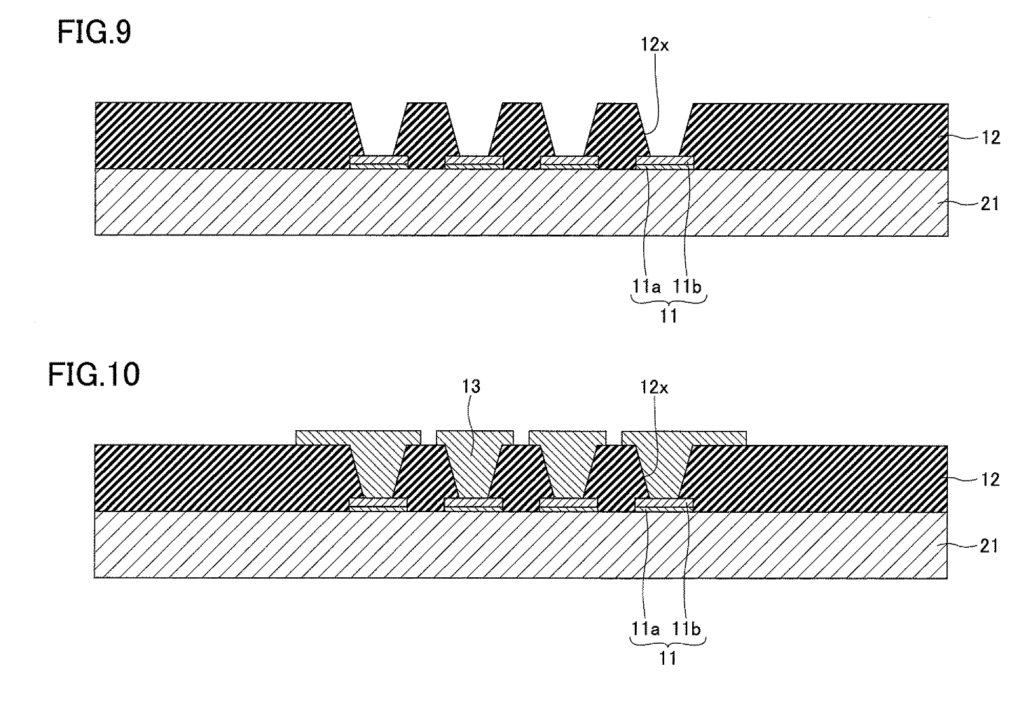

Referring to FIG. 8, after removing the resist layer 22 illustrated in FIG. 7, the first insulating layer 12 is formed on the one surface of the supporting body 21 so as to cover the first wiring layer 11. The material of the first insulating layer 12 may be a thermosetting insulating resin such as a film-like epoxy resin and a film-like polyimide resin or a thermosetting insulating resin such as a liquid-like or paste-like epoxy resin and a liquid-like or paste-like polyimide resin. The first insulating layer 12 is preferably a resin material containing a filler and having good workability to enable easily forming a first via hole 12x by a laser processing method or the like in the step illustrated in FIG. 9 described below. The thickness of the first insulating layer 12 may be about 50 μm.

When the thermosetting insulating resin such as a film-like epoxy or polyimide resin is used as the material of the first insulating layer 12, the film-like first insulating layer 12 may be laminated on the one face of the supporting body 21 so as to cover the first wiring layer 11. After pressing the laminated first insulating layer 12, the first insulating layer 12 is heated at the curing temperature or more and cured or hardened. It is possible to prevent a void from being caused by laminating the first insulating layer 12 under a vacuum atmosphere.

When the thermosetting insulating resin such as a liquid-like epoxy or polyimide resin and a paste-like epoxy or polyimide resin is used as the material of the first insulating layer 12, the liquid-like or paste-like first insulating layer 12 may be laminated on the one face of the supporting body 21 so as to cover the first wiring layer 11. The coated first insulating layer 12 is heated at the curing temperature or more to harden the first insulating layer 12.

Referring to FIG. 9, first via holes 12x which penetrate the first insulating layer 12 and from which the faces of the first wiring layers 11 are exposed are formed. The first via hole 12x may be formed by a laser processing method using, for example, a CO₂ laser. The first via holes 12x may be formed by using a photosensitive resin for the first insulating layer 12, and patterning the first insulating layer 12 with photolithography. Further, the first via holes 12x may be formed by printing a liquid-like or paste-like resin through a screen mask for masking a position corresponding to the first via hole 12x and curing the resin.

Referring to FIG. 10, the second wiring layers 13 are formed on the first insulating layer 12. The second wiring layers 13 include via wirings filled inside the first via holes 12x and a wiring pattern formed on the first insulating layer 12. The second wiring layers 13 are electrically connected to the first wiring layers 11 exposed toward the first via holes 12x. The material of the second wiring layers 13 may be made of copper (Cu) or the like.

The second wiring layers 13 may be formed by various wiring forming methods such as a semi-additive method and a subtractive method. As an example, a method of forming the second wiring layers 13 using the semi-additive method as an example is descried next.

First, a seed layer (not illustrated) made of copper (Cu) or the like is formed on the upper surfaces of the first wiring layers 11 exposed inside the first via holes 12x and on the first insulating layer 12 including inner walls of the first via hole 12x by an electroless plating or sputtering method. Further, a resist layer (not illustrated) having opening portions corresponding to the second wiring layers 13 is formed on the seed layer. A wiring layer (not illustrated) made of copper (Cu) is formed on the opening portions of the resist layer by the electro plating in which the seed layer is used as the power supplying layer. Subsequently, after removing the resist layer, a portion of the seed layer which is not covered by the wiring layers is removed by etching using the wiring layer as a mask. With this, the second wiring layers 13 include the via wirings filled inside the first via holes 12x in the first insulating layer 12 and the wiring patterns formed on the first insulating layer 12.

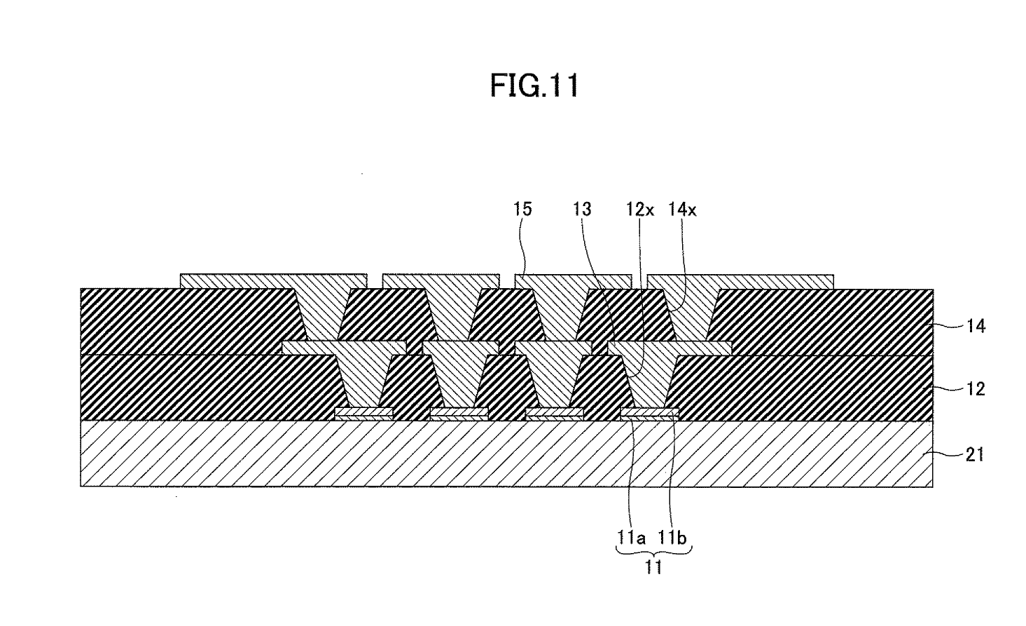

Referring to FIG. 11, by repeating the above processes, the second insulating layer 14 and the third insulating layer 15 are laminated on the first insulating layer 12. Said differently, after forming the second insulating layer 14 covering the second wiring layers 13 on the surface 12b of the first insulating layer 12, second via holes 14x are formed at portions of the second insulating layer 14 provided on the second wiring layers 13. The material of the second insulating layer 14 may be a thermosetting insulating resin such as a film-like epoxy resin and a film-like polyimide resin or a thermosetting insulating resin such as a liquid-like or paste-like epoxy resin and a liquid-like or paste-like polyimide resin.

Further, third wiring layers 15 to be connected to the second wiring layers 13 are formed on the second insulating layer 14 via the second via holes 14x. The material of the third wiring layers 15 may be copper (Cu) or the like. The third wiring layers 15 may be formed by the semi-additive method.

As described, a predetermined buildup wiring layer is formed on the one face of the supporting body 21. With this Embodiment, the two-layered buildup wiring layer including the second wiring layers 13 and the third wiring layers 15 is formed, and an n-layered buildup wiring layer (n is an integer of 1 or more) can be formed.

Referring to FIG. 12, the third insulating layer 16 having opening portions 16x is formed to cover the third wiring layers 15 on the second insulating layer 14. Specifically, the liquid-like or paste-like epoxy resin, which contains the predetermined pigment described above and has the reflectance peak of the visible ray in any wavelength in a purple to blue wavelength range satisfying 385 nm<the wavelength≦495 nm, is coated by a spin-coat method or the like on the second insulating layer 14 so as to cover the third wiring layers. When the coated epoxy resin is a photosensitive resin, the opening portions 16x are formed by irradiating the coated epoxy resin with a light and developing the coated epoxy resin. Further, when the coated epoxy resin is not the photosensitive resin, the coated epoxy resin is heated to have a temperature of the curing temperature or more to cure the coated epoxy resin. Thereafter, the opening portions 16x may be formed by a laser processing method using a CO₂ laser.

Meanwhile, a film-like epoxy resin containing the predetermined pigment which has the reflectance peak of the visible ray in any wavelength in a purple to blue wavelength range satisfying 385 nm<the wavelength≦495 nm described above may be laminated on the second insulating layer to cover the third wiring layers 15, instead of coating the liquid-like or paste-like epoxy resin containing the predetermined pigment.

With this, the third insulating layer 16 having the opening portions 16x may be formed. Parts of the third wiring layers 15 are exposed inside the opening portions 16x of the third insulating layers 16. The third wiring layers 15 exposed inside the opening portions 16x function as electrode pads for electrically connecting to pads installed in a mounting board (not illustrated) such as a mother board.

When necessary, a metallic layer or the like may be formed on the third wiring layers 15 which are exposed toward insides of the opening portions 18x. An example of the metallic layer is an Au layer, a Ni/Au layer which is a metallic layer formed by laminating a Ni layer and an Au layer in this order, a Ni/Pd/Au layer which is a metallic layer formed by laminating a Ni layer, a Pd layer, and an Au layer in this order or the like.

After the process illustrated in FIG. 12, the wiring substrate illustrated in FIG. 3 and FIG. 4 is completed by removing the supporting body 21. The supporting body 21 made of the copper foil may be removed by wet etching using aqueous ferric chloride, aqueous copper chloride, aqueous ammonium persulfate, or the like. At this time, the outermost layer of the first wiring layer 11 exposing from the first insulating layer 12 is a gold (Au) film. Therefore, only the supporting body 21 formed by the copper foil can be selectively etched. When the third wiring layer 15 is made of copper (Cu), the third wiring layer 15 may be masked in order to prevent the third wiring layer 15 from being etched together with the supporting body 21.

Although the third insulating layer 16 is recognized as any color in a range from purple to blue as described above, it is possible to use an insulating layer recognized as any color in the range from purple to blue for another insulating layer.

Although the third insulating layer 16 is recognized as any color in a range from purple to blue as described above, it is possible to use an insulating layer recognized as any color in the range from purple to blue for the first insulating layer 12 in place of the third insulating layer 16. In this case, it is possible to improve a degree in which the lower wiring layer is seen through by making it difficult to see through when the wiring substrate is viewed from the first insulating layer 12 in comparison with the example described above in Japanese Patent No. 3821993.

As described above, the first wiring layers 11 exposing out of the first insulating layer 12 are the electrode pads to be connected to the semiconductor chip or the like, and the third wiring layers 15 exposing out of the opening portions 16x are the external connection terminals or parts on which the external connection terminals are formed. However, the first wiring layers 11 exposing from the first insulating layer 12 may be the external connection terminals or parts on which the external connection terminals are formed, and the third wiring layers 15 exposed toward inside of the opening portion 16x may be the electrode pads to be connected to the semiconductor chips. In this case, the pitch of the third wiring layers 15 exposed inside the opening portions 16x becomes narrow in comparison with the pitch of the first wiring layer 11 exposed from the first insulating layer 12.

As such, with this Embodiment, the uppermost insulating layer can be recognized as any color in the range from purple to blue. Said differently, a material having a reflectance peak of the visible light in a wavelength range from purple to blue satisfying 385 nm<the wavelength≦495 nm may be used as the material for the uppermost layer. As a result, it is possible to improve the degree in which the lower wiring layer is seen through in comparison with the example described above in Japanese Patent No. 3821993.

Further, since the lower wiring layer is difficult to see through, it is possible to reduce a rate in which the lower wiring layer is recognized to be defective in an appearance inspection using image recognition to thereby improve an accuracy and efficiency of the appearance inspection.

Further, since the lower wiring layer is difficult to see through, it is possible to prevent pattern information of the lower wiring layer from leaking outside.

### Examples 1 to 6 and Comparative Examples 1 to 6

In simulations of Examples 1 to 6, a degree in which the lower wiring layer is seen through is digitized as a luminance difference when the uppermost insulating layer is recognized as any color in a range from purple to blue satisfying 385 nm<the wavelength≦495 nm. In simulations of Comparative Examples 1 to 6, a degree in which the lower wiring layer is seen through is digitized as the luminance difference when the uppermost insulating layer is recognized as any color in a range from green to red satisfying 495 nm<the wavelength≦750 nm.

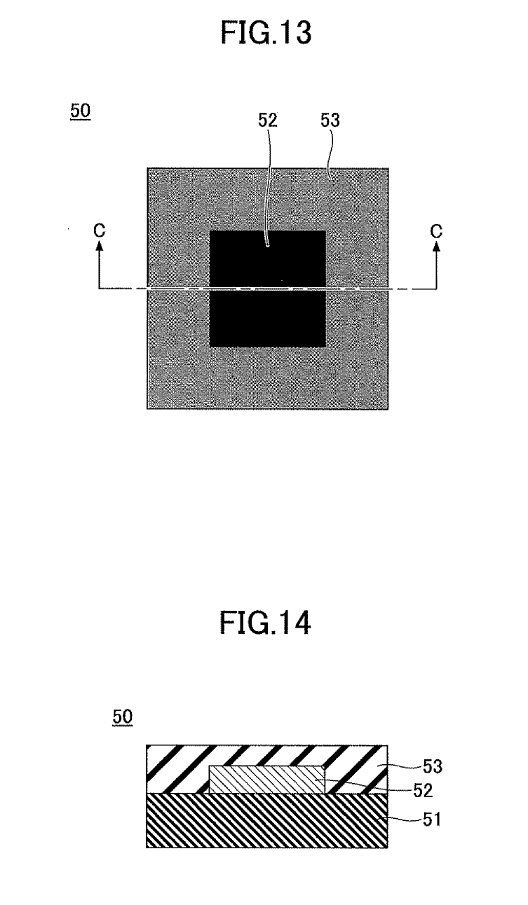

FIG. 13 is a plan view of an example wiring substrate used for the simulation. FIG. 14 is a cross-sectional view taken along a line C-C of FIG. 13. Referring to FIG. 13 and FIG. 14, an example wiring substrate 50 has a structure in which a first insulating layer 51, a wiring layer 52 and a second insulating layer 53 are sequentially laminated. Said differently, the wiring layer 52 is formed on the first insulating layer 51, and the second insulating layer 53 is further formed on the first insulating layer 51 so as to cover the wiring layer 52.

In the simulation of the Examples and Comparative Examples, the first insulating layer 51 and the second insulating layer 53 are colored by the same color, and the wiring layer 52 is colored by a color different from the color of the first insulating layer 51 and the second insulating layer 53. Transmission factors of the first insulating layer 51, the second insulating layer 53 and the wiring layer 52 are 50% respectively. Specific color combinations of the first insulating layer 51, the second insulating layer 53 and the wiring layer 52 are listed in Table 1 as follows.

In the Examples and Comparative Examples, software for image processing is used to convert the colors of the wiring layer 52 and the second insulating layer 53 into 256 colors and to further convert to a gray scale. Then, the maximum values and minimum values of luminance of the wiring layer and the second insulating layer 53 are measured. Then, differences between the maximum values and minimum values of the measured luminance are compared. The software for image processing is “Easy Access” manufactured by EURESYS s.a. (“Easy Access” is a registered trademark).

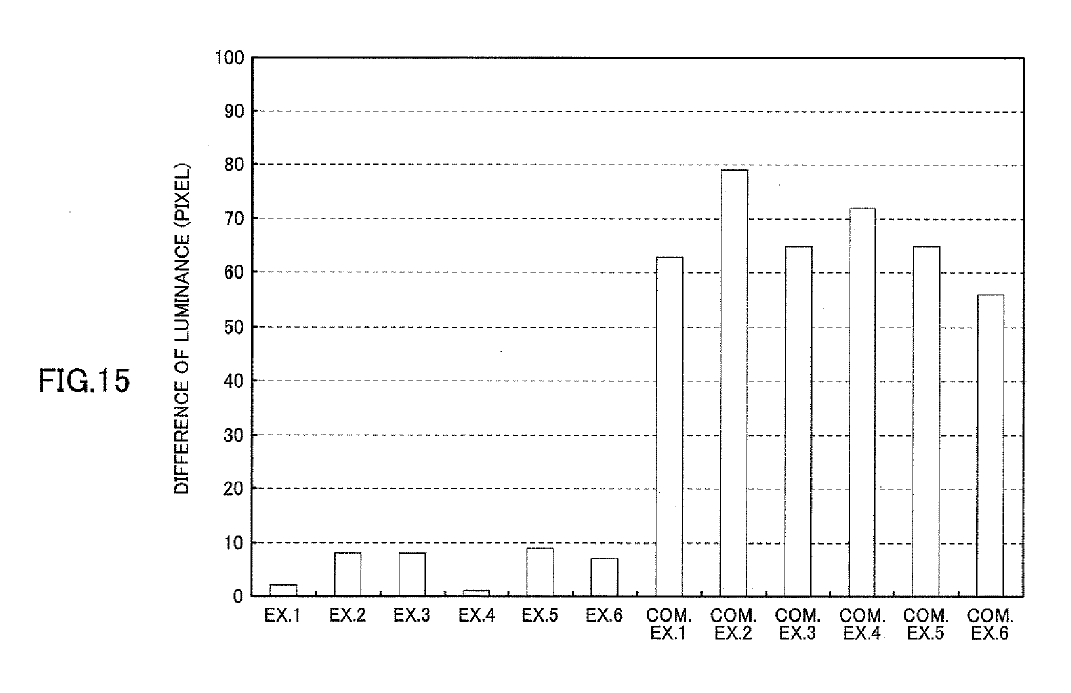

Table 1 illustrates the Examples and the Comparative Examples. FIG. 15 illustrates the luminance difference between the wiring layer 52 and the second insulating layer 53, which is a graph of the luminance difference listed in Table 1. In Table 1 and FIG. 5, “EX. 1” stands for Example 1; “EX. 2” stands for Example 2; “EX. 3” stands for Example 3; “EX. 4” stands for Example 4; “EX. 5” stands for Example 5; “EX. 6” stands for Example 6; “COM. EX. 1” stands for Comparative Example 1; “COM. EX. 2” stands for Comparative Example 2; “COM. EX. 3” stands for Comparative Example 3; “COM. EX. 4” stands for Comparative Example 4; “COM. EX. 5” stands for Comparative Example 5; “COM. EX. 6” stands for Comparative Example 6; “2ND. I.L”. stands for the second Insulating layer; “W.L.” stands for the wiring layer; “CONVERTED IMAGE” stands for the image converted to gray scale; “MIN” stands for the minimum value of the luminance; “MAX” stands for the maximum value of the luminance; and “DEF” stands for the difference between the maximum value and the minimum value of the luminance.

In Table 1, the wavelength range of purple is determined to be 385 nm<the wavelength≦450 nm, the wavelength range of blue is determined to be 450 nm<the wavelength≦495 nm, the wavelength range of green is determined to be 495 nm<the wavelength≦570 nm, the wavelength range of yellow is determined to be 570 nm<the wavelength≦590 nm, and the wavelength range of red is determined to be 620 nm<the wavelength≦750 nm. The luminance is calculated by the software for the image processing and expressed by numbers of 0 through 255 (integers) having a unit of “pixel(s)”. When the luminance difference is zero, the lower wiring layer cannot be completely seen through. The closer to zero the luminance difference is, the smaller is a degree in which the lower wiring layer is seen through (harder to be see through).

TABLE 1

| | COLOR | | CONVERTED | LUMINANCE | | |
|---|---|---|---|---|---|---|
| | 2NDI.L | W.L. | IMAGE | MIN | MAX | DEF |
| EX. 1 | PURPLE | GREEN | 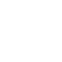 | 147 | 149 | 2 |
| EX. 2 | | YELLOW | 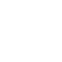 | 149 | 157 | 8 |
| EX. 3 | | RED | 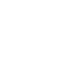 | 141 | 149 | 8 |
| EX. 4 | BLUE | GREEN | 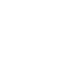 | 209 | 210 | 1 |
| EX. 5 | | YELLOW | 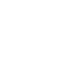 | 210 | 219 | 9 |
| EX. 6 | | RED | 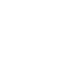 | 203 | 210 | 7 |
| COM. EX. 1 | GREEN | YELLOW | 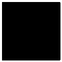 | 43 | 106 | 63 |
| COM. EX. 2 | | RED | 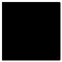 | 27 | 106 | 79 |
| COM. EX. 3 | YELLOW | GREEN | 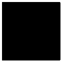 | 62 | 127 | 65 |
| COM. EX. 4 | | RED | 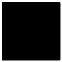 | 55 | 127 | 72 |
| COM. EX. 5 | RED | GREEN | 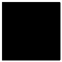 | 22 | 87 | 65 |
| COM. EX. 6 | | YELLOW | 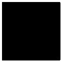 | 31 | 87 | 56 |

As in Comparative Examples 1 through 6 of Table 1 and FIG. 15, when the second insulating layer (uppermost insulating layer) is recognized as any color in the range from green to red (495 nm<the wavelength≦750 nm), the luminance difference of the wiring layer and the second insulating layer is 56 or more being relatively large, and the lower wiring layer is easily seen through. As in Table 1 and Examples 1 through 6, when the second insulating layer (uppermost insulating layer) is recognized as any color in the range from purple to blue (385 nm<the wavelength≦495 nm), the luminance difference between the wiring layer and the second insulating layer is a single figure, and the lower wiring layer is not easily seen through. This result can be confirmed by comparing images obtained by converting to the gray scales of Examples 1 through 6 with images obtained by converting to the gray scales of Comparative Examples 1 through 6.

As described, in the simulation of Examples 1 through 6 and Comparative Examples 1 through 6, it is confirmed that the degree in which the lower wiring layer is seen through can be improved (hard to be seen through) in comparison with the example described above in Japanese Patent No. 3821993 when a material having the reflectance peak of the visible light in any wavelength in the wavelength range from purple to blue (385 nm<the wavelength≦495 nm) is used for the uppermost insulating layer.

In Examples 1 through 6 and Comparative Examples 1 through 6, the color of the wiring layer is set in a range from green to red (495 nm<the wavelength≦750 nm). Copper (Cu) or gold (Au) is practically used as a material of the wiring layer and has a reflectance for light in a range from yellow to red (570 nm<the wavelength≦750 nm), which is high. Therefore, the conditions of the simulation are suitable for a practical application.

In the Embodiment, the example of applying to the coreless wiring substrate manufactured by a build-up manufacturing method is explained. However, the Embodiment is not limited to this and is applicable to various wiring substrates. Specifically, the Embodiment is applicable to a single-sided (one layer) wiring substrate in which only one side of the substrate has a wiring layer, a double-sided (two layer) wiring substrate in which both sides of the substrate have wiring layers, a through-type multilayer wiring substrate connecting wiring layers by through vias, an Interstitial Via Hole (IVH) multilayer wiring substrate connecting a specific wiring layer using the IVH, or the like.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A wiring substrate comprising:
a wiring layer; and
an insulating layer configured to cover the wiring layer,
wherein the insulating layer is recognized to have any color in a range from purple to blue.

2. The wiring substrate according to claim 1,
wherein the insulating layer recognized as the any color in the range from purple to blue is made of a material having a reflectance peak of a visible light in a wavelength satisfying a relationship of 385 nm<the wavelength≦495 nm.

3. The wiring substrate according to claim 2,
wherein the material is an insulating resin containing a polycyclic pigment or an inorganic pigment.

4. The wiring substrate according to claim 1,
wherein the wiring layer covered by the insulating layer recognized to have the any color in the range from purple to blue is made of a material having a reflectance peak of a visible light in a wavelength range satisfying a relationship of 495 nm<the wavelength≦750 nm.

5. A wiring substrate comprising:
a plurality of wiring layers; and
a plurality of insulating layers,
wherein the plurality of wiring layers and the plurality of insulating layers are alternately laminated, and
the uppermost insulating layer covering the uppermost wiring layer is recognized to have any color in a range from purple to blue.

6. The wiring substrate according to claim 5,
wherein the insulating layer recognized as the any color in the range from purple to blue is made of a material having a reflectance peak of a visible light in a wavelength satisfying a relationship of 385 nm<the wavelength≦495 nm.

7. The wiring substrate according to claim 6,
wherein the material is an insulating resin containing a polycyclic pigment or an inorganic pigment.

8. The wiring substrate according to claim 5,
wherein the wiring layer covered by the insulating layer recognized to have the any color in the range from purple to blue is made of a material having a reflectance peak of a visible light in a wavelength range satisfying a relationship of 495 nm<the wavelength≦750 nm.
